(19) United States
(12) Patent Application Publication
(10) Pub. No.: US 2026/0319981 A1
(43) Pub. Date: Oct. 15, 2026

(54) SWITCHING AWARE DATA ENCODING FOR DATA TRANSFERS

(71) Applicant: QUALCOMM Incorporated, San Diego, CA (US)

(72) Inventors: Mahdi NAZM BOJNORDI, San Diego, CA (US); Paul Nicholas WHATMOUGH, Cambridge, MA (US)

(21) Appl. No.: 19/176,026

(22) Filed: Apr. 10, 2025

(51) Int. Cl. G06F 13/36

(52) U.S. Cl. CPC G06F 13/36; G06F 2213/40

(57) ABSTRACT

A method for data processing includes creating a bit selection mask and partitioning input data sequences with the bit selection mask into clusters. Each cluster has an original cluster identifier (ID). The method further includes calculating majority bit patterns for each cluster. The method still further includes remapping the original cluster IDs into new cluster IDs based on Hamming weights and a quantity of data sequences within each cluster. The method also includes generating code patterns by modifying each majority bit pattern of each cluster based on the respective new cluster ID. The method includes calculating codewords for each cluster based on the data sequences in the respective cluster and the respective code pattern. The method further includes replacing the input data sequences with the codewords to create a code.

### BACKGROUND

### Field

Aspects of the present disclosure relate to computing systems, and more specifically to encoding data to save power during data transfers.

### Background

Mobile or portable computing devices include mobile phones, laptop, palmtop and tablet computers, portable digital assistants (PDAs), portable game consoles, and other portable electronic devices. Mobile computing devices are comprised of many electrical components that consume power and generate heat. The components (or compute devices) may include system-on-a-chip (SoC) devices, graphics processing unit (GPU) devices, neural processing unit (NPU) devices, digital signal processors (DSPs), and modems, among others. It would be desirable to improve power consumption by computing devices.

### SUMMARY

In aspects of the present disclosure, a method for data processing includes creating a bit selection mask. The method also includes partitioning input data sequences with the bit selection mask into clusters. Each cluster has an original cluster identifier (ID). The method further includes calculating majority bit patterns for each cluster. The method still further includes remapping the original cluster IDs into new cluster IDs based on Hamming weights and a quantity of data sequences within each cluster. The method also includes generating code patterns by modifying each majority bit pattern of each cluster based on the respective new cluster ID. The method also includes calculating codewords for each cluster based on the data sequences in the respective cluster and the respective code pattern. The method further includes replacing the input data sequences with the codewords to create a code.

Other aspects of the present disclosure are directed to an apparatus. The apparatus has a one or more memories and one or more processors coupled to the one or more memories. The processor(s) is configured to create a bit selection mask. The processor(s) is also configured to partition input data sequences with the bit selection mask into clusters. Each cluster has an original cluster identifier (ID). The processor(s) is further configured to calculate majority bit patterns for each cluster. The processor(s) is still further configured to remap the original cluster IDs into new cluster IDs based on Hamming weights and a quantity of data sequences within each cluster. The processor(s) is also configured to generate code patterns by modifying each majority bit pattern of each cluster based on the respective new cluster ID. The processor(s) is configured to calculate codewords for each cluster based on the data sequences in the respective cluster and the respective code pattern. The processor(s) is further configured to replace the input data sequences with the codewords to create a code.

In other aspects of the present disclosure, a non-transitory computer-readable medium with program code recorded thereon is disclosed. The program code is executed by a processor and includes program code to create a bit selection mask. The program code also includes program code to partition input data sequences with the bit selection mask into clusters. Each cluster has an original cluster identifier (ID). The program code further includes program code to calculate majority bit patterns for each cluster. The program code still further includes program code to remap the original cluster IDs into new cluster IDs based on Hamming weights and a quantity of data sequences within each cluster. The program code includes program code to generate code patterns by modifying each majority bit pattern of each cluster based on the respective new cluster ID. The program code also includes program code to calculate codewords for each cluster based on the data sequences in the respective cluster and the respective code pattern. The program code further includes program code to replace the input data sequences with the codewords to create a code.

This has outlined, rather broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for carrying out the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates an example implementation of a host system-on-a-chip (SoC), including a data encoder and a data decoder, in accordance with certain aspects of the present disclosure.

FIG. 2 is a diagram illustrating relative energy costs for various computer system operations, in accordance with various aspects of the present disclosure.

FIGS. 3 and 4 are circuit diagrams illustrating interconnect energy, in accordance with various aspects of the present disclosure.

FIG. 5 is a diagram illustrating a bit selection mask for data encoding, in accordance with various aspects of the present disclosure.

FIG. 6 is a diagram illustrating clustering input data, in accordance with various aspects of the present disclosure.

FIG. 7 is a table illustrating cluster identifier (ID) generation, in accordance with various aspects of the present disclosure.

FIGS. 8A, 8B, and 9 are diagrams illustrating calculating of majority bit patterns, in accordance with various aspects of the present disclosure.

FIGS. 10A, 10B, and 11 are diagrams illustrating remapping of cluster identifiers (IDs), in accordance with various aspects of the present disclosure.

FIGS. 12A, 12B, and 13 are diagrams illustrating coding pattern generation, in accordance with various aspects of the present disclosure.

FIGS. 14A-14C are diagrams illustrating codeword calculation, in accordance with various aspects of the present disclosure.

FIGS. 15A-15C are diagrams illustrating data value replacement, in accordance with various aspects of the present disclosure.

FIG. 16 is a diagram illustrating data decoding, in accordance with various aspects of the present disclosure.

FIG. 17 is a flow diagram illustrating an example process performed, for example, by a computing device, in accordance with various aspects of the present disclosure.

FIG. 18 is a block diagram showing an exemplary wireless communications system in which a configuration of the present disclosure may be advantageously employed.

FIG. 19 is a block diagram illustrating a design workstation used for circuit, layout, and logic design of components, in accordance with various aspects of the present disclosure.

### DETAILED DESCRIPTION

The detailed description set forth below, in connection with the appended drawings, is intended as a description of various configurations and is not intended to represent the only configurations in which the concepts described may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

As described, the use of the term “and/or” is intended to represent an “inclusive OR,” and the use of the term “or” is intended to represent an “exclusive OR.” As described, the term “exemplary” used throughout this description means “serving as an example, instance, or illustration,” and should not necessarily be construed as preferred or advantageous over other exemplary configurations. As described, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described, the term “proximate” used throughout this description means “adjacent, very near, next to, or close to.” As described, the term “on” used throughout this description means “directly on” in some configurations, and “indirectly on” in other configurations.

Power consumption is a key variable for systems-on-a-chip (SoCs), as power limits performance. By reducing a quantity of digital ones (1s) being moved during a data transfer by a compute device, data movement energy and corresponding power consumption can be reduced. Reducing the number of ones (1s) also inherently reduces the amount of switching between 1s and zeros (0s). Artificial intelligence (AI) inference has high energy and power costs. Large model inference, such as with large language models (LLMs), consumes substantial power and involves a large amount of data movement. Model weights are associated with large data transfers and significant energy consumption. Reducing weight energy is crucial for efficient model inference, especially on portable and mobile devices.

It would be desirable to encode data in such a way as to reduce the number of ones (1s), thereby reducing dynamic power consumption. Aspects of the present disclosure encode stationary and semi-stationary data using a customized low-energy representation to save data transfer power. An encoder of the present disclosure generates a sequence of codewords for input data. These codewords are specifically created based on the frequency of ones (1s) in the input data (e.g., bit sequences). During the encoding process, a pattern table is generated alongside the encoded values. To reduce overhead, only a limited number of patterns are maintained in the table. The decode process includes low power operations (e.g., table lookups and logical exclusive OR (XOR) operations) to reduce overhead.

Particular aspects of the subject matter described in this disclosure can be implemented to realize one or more of the following potential advantages. In some examples, the described encoding and decoding techniques enable power saving during data movement.

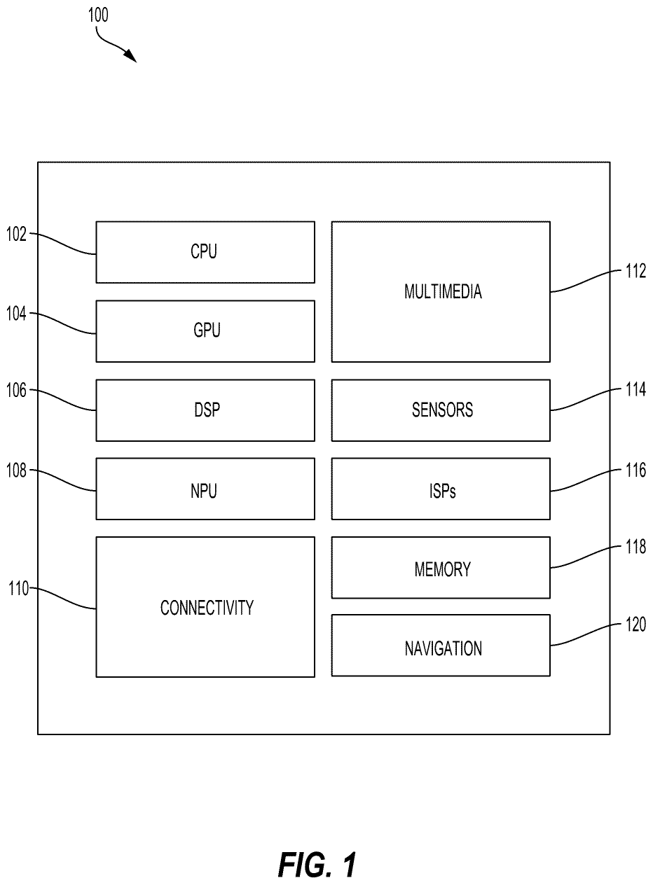

FIG. 1 illustrates an example implementation of a host system-on-a-chip (SoC) 100, which includes a data encoder and decoder, in accordance with aspects of the present disclosure. The host SoC 100 includes processing blocks tailored to specific functions, such as a connectivity block 110. The connectivity block 110 may include fifth generation (5G) connectivity, fourth generation long term evolution (4G LTE) connectivity, WI-FI connectivity, universal serial bus (USB) connectivity, Bluetooth® connectivity, Secure Digital (SD) connectivity, and the like.

In this configuration, the host SoC 100 includes various processing units that support multi-threaded operation. For the configuration shown in FIG. 1, the host SoC 100 includes a multi-core central processing unit (CPU) 102, a graphics processor unit (GPU) 104, a digital signal processor (DSP) 106, and a neural processor unit (NPU) 108. The host SoC 100 may also include a sensor processor 114, image signal processors (ISPs) 116, a navigation module 120, which may include a global positioning system (GPS), and a memory 118. The multi-core CPU 102, the GPU 104, the DSP 106, the NPU 108, and the multi-media engine 112 support various functions such as video, audio, graphics, gaming, artificial networks, and the like. Each processor core of the multi-core CPU 102 may be a reduced instruction set computing (RISC) machine, an advanced RISC machine (ARM), a microprocessor, or some other type of processor. The NPU 108 may be based on an ARM instruction set.

According to aspects of the present disclosure, a computing device includes a switching aware data encoder. The encoder may include means for creating, means for partitioning, means for calculating, means for remapping, means for generating, means for replacing, means for retrieving, means for performing, means for selecting, means for determining, means for shifting, means for counting, and means for setting. In one configuration, the creating means, the partitioning means, the calculating means, the remapping means, the generating means, the replacing means, the retrieving means, the performing means, the selecting means, the determining means, the shifting means, the counting means, and the setting means may be the CPU 102, GPU 104, DSP 106, and/or NPU 108, as shown in FIG. 1. In other aspects, the aforementioned means may be any structure or any material configured to perform the functions recited by the aforementioned means.

Power consumption is a key variable for SoCs, as power limits performance. Power is the rate of consuming energy, or the rate of doing work. That is,

$$Power = \frac{energy}{time} .$$

Power comprises two components: static power and dynamic power. That is Power=VI_{static}+αCV²f, where V is the supply voltage, I is current, α is the activity factor, C is the switching capacitance, and f is the clock frequency.

There exist two tiers of power optimization: system and content. For system optimization, the V, C, and f values are controlled. The goal with system power optimization is to control or change physical characteristics to save power. Examples include low power devices, voltage scaling, clock gating, dynamic voltage and frequency scaling (DVFS), physical layout, low power routing, etc. For content optimization, the a values are controlled, in other words, activity is reduced to lower power. For example, activity in the compute core may be reduced by exploiting sparsity, look-up table (LUT)-based computation, memorization, etc. Activity of data movement may be reduced by reducing movement distance, data volume, or reducing a number of switching or a number of ones (1s) being processed. By reducing the number of ones (1s), switching is also inherently reduced.

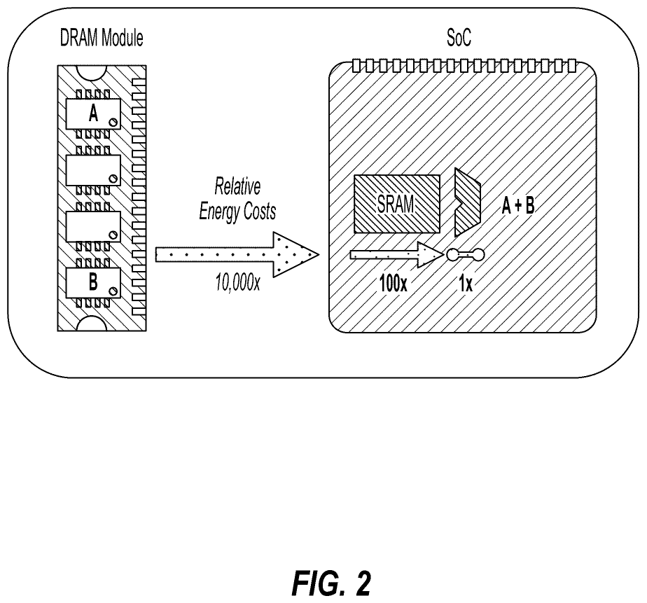

FIG. 2 is a diagram illustrating relative energy costs for various computer system operations, in accordance with various aspects of the present disclosure. As seen in FIG. 2, data movement energy cost from off-chip memory (e.g., dynamic random access memory (DRAM) module) is 10,000 times higher than the energy cost of a logical AND operation (e.g., A+B). Movement from on-chip memory (e.g., static random access memory (SRAM)) in the SoC to the processor consumes 100 times more energy than the energy of the processor operation itself.

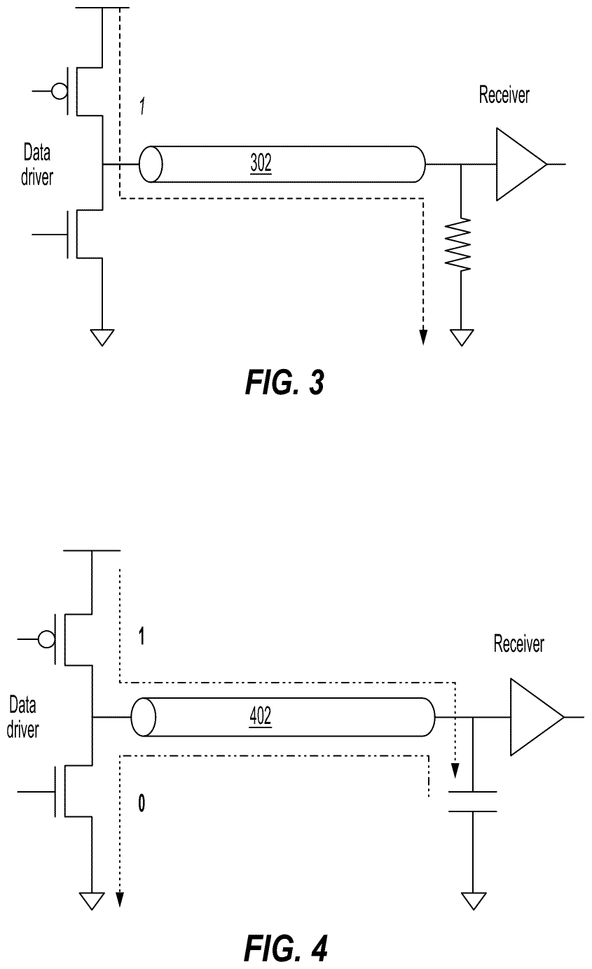

FIGS. 3 and 4 are circuit diagrams illustrating interconnect energy, in accordance with various aspects of the present disclosure. As seen in FIG. 3, terminated interconnects (e.g., off-chip) consume energy when transferring a ‘1’. By reducing the number of ‘1s’ (e.g., Hamming weight), lower energy consumption may be achieved on a DRAM interface 302. As seen in FIG. 4, for unterminated interconnects (e.g., on-chip), energy is consumed during transitions between states. Transition-aware data encoding can reduce the number of transitions (e.g., Hamming distance between consecutive values), thereby saving energy.

The encoding and decoding techniques of the present disclosure, may be integrated into various machine learning (ML) inference systems, ranging from edge devices to data centers, to reduce energy and power consumption for large ML models. One particular application is in large language models (LLMs), which transfer a substantial number of weights from DRAM for each inference task. The weights may be pre-computed and repeatedly accessed on a large number of occasions. Both a software-only approach for existing computer processing unit (CPU), graphics processing unit (GPU), and neural processing unit (NPU) processors, as well as a specialized hardware solution, are feasible for implementing the proposed encoding and decoding techniques.

Artificial intelligence (AI) inference has high energy and power costs. Large model inference, such as with large language models (LLMs), consumes substantial power and involves a large amount of data movement. Reducing weight energy is crucial for efficient model inference, especially on portable and mobile devices. Existing performance optimizations are often power-agnostic and unable to optimize energy efficiency.

Weights are associated with large data transfers and significant energy consumption. During the decoder (e.g., token generation) phase, the majority of transferred data is weights. In the prefill (e.g., prompt processing) phase, a sizable portion of data transfer consists of weights. It would be desirable to encode data in such a way as to reduce the number of ones (1s), thereby reducing dynamic power consumption.

Aspects of the present disclosure encode stationary and semi-stationary data using a customized low-energy representation to save data transfer power. The encoding applies to many types of data, such as weights and key value (KV) cache data during large language model inference. Weights are stationary as they are created before runtime. Weights may be encoded using an offline, one time process. Key-value (KV) cache data is semi-stationary because the data is created at runtime and reused multiple times. KV cache data benefits from a lightweight version of the proposed encoding at runtime.

An encoder of the present disclosure generates a sequence of codewords for input data. These codewords are specifically created based on the frequency of ones (1s) in the input data (e.g., bit sequences). During the encoding process, a pattern table is generated alongside the encoded values. To reduce overhead, only a limited number of patterns are maintained in the table. In some implementations, the table is small enough to be stored in register files, for example in a GPU. If a large amount of input data is present, the input data may be divided into multiple segments, each with its own pattern table, to ensure high energy savings. The encoding process repeats for each segment.

According to further aspects of the present disclosure, a decoder retrieves the original data from the codewords. The same pattern table is used for each data segment to decode the codewords before use. The decode process includes low power operations (e.g., table lookups and logical exclusive OR (XOR) operations) to reduce overhead.

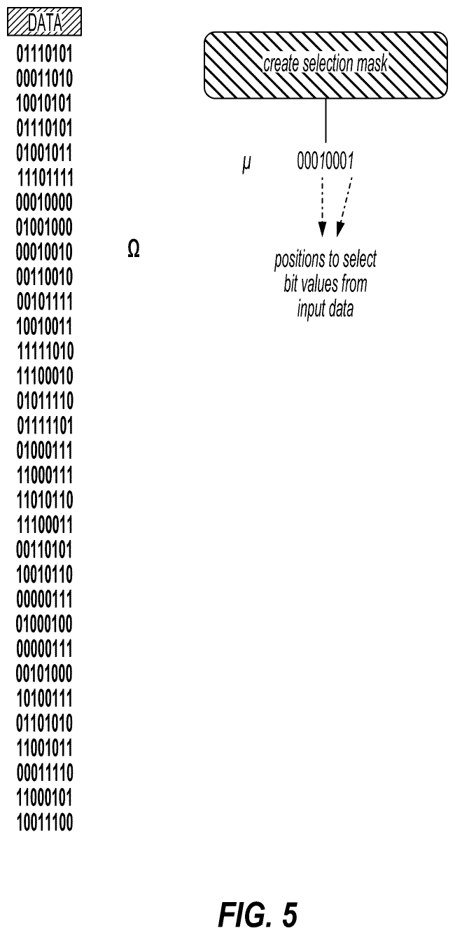

FIG. 5 is a diagram illustrating a bit selection mask for data encoding, in accordance with various aspects of the present disclosure. In the example of FIG. 5, a bit selection mask μ is created for partitioning/clustering input data (also referred to as input data sequences, or input sequences) Ω. The bit selection mask μ is generated based on the input data Ω. For an input data sequence Ω with d-bit values, a bit selection mask μ (that includes a first quantity d of bits and a second quantity b of 1s) is generated. The 1s in the mask μ determine the bit positions of each input value for generating an identifier (ID).

The selection mask μ may be generated online or offline. The selection mask may also be referred to as a bit selection mask. A predefined or random mask may be defined at runtime to keep the encoding process lightweight for semi-stationary data (e.g., KV cache data). An offline encoding mechanism can explore all possible values of b and the positions of the 1s within the selection mask μ for stationary data (e.g., weights). That is, the quantity b of 1s and their position within the selection mask μ are evaluated. Ultimately, a mask value resulting in the lowest number of 1s in the codewords is selected.

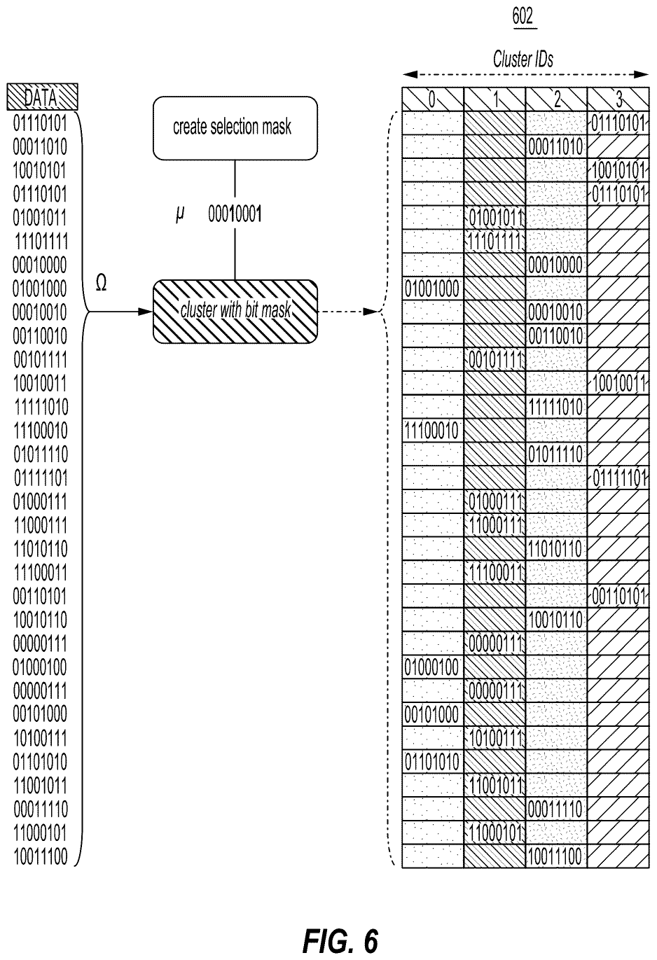

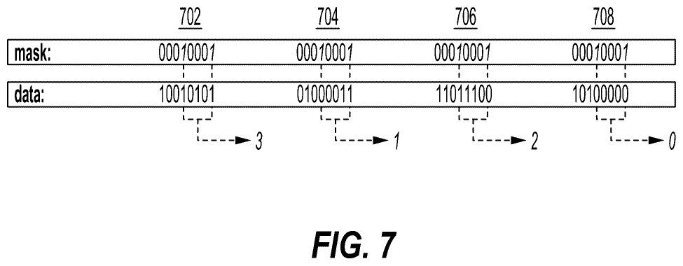

FIG. 6 is a diagram illustrating clustering of input data, in accordance with various aspects of the present disclosure. FIG. 7 is a table illustrating cluster ID generation, in accordance with various aspects of the present disclosure. In the example of FIG. 6, input data Ω is clustered into multiple subsets using a selection mask μ. A cluster ID is generated for each subset of the input data Q, as seen in the example of FIG. 7. For example, if a mask value bitwise logically AND'ed with a data sequence results in 1s at both bit positions of the 1s in the selection mask μ (as seen in a first column 702), then the cluster ID is 3 because the leftmost 1 value is shifted right to the second rightmost bit position, resulting in the binary value 11=3. If the mask value logically AND'ed with a data sequence value results in a 1 at the rightmost bit position of the 1s in the selection mask μ (as seen in a second column 704), then the cluster ID is 1 because the leftmost 0 is shifted right resulting in the binary value 01=1. If the mask value logically AND'ed with a data sequence value results in a 1 at the leftmost bit position of the 1s in the selection mask μ (as seen in a third column 706), then the cluster ID is 2 because the leftmost 1 is shifted right resulting in the binary value 10=2. If the mask value logically AND'ed with a data sequence value results in 0s at both bit positions of the 1s in the selection mask μ (as seen in the last column 708), then the cluster ID is 0 because the leftmost 0 is shifted right resulting in the binary value 00=0.

A maximum number of clusters is determined by 2^{b}, where b is the number of 1s in the selection mask μ. The number is a maximum because it is possible that some clusters have no sequences, depending on the original input sequences Ω. The input sequences Ω are assigned to clusters based on their computed IDs. For example, as seen in FIG. 6, the first data sequence 01110101 bitwise logically AND'ed with the mask 00010001 sorts the first data sequence into cluster 3. The second data sequence 00011010 bitwise logically AND'ed with the mask 00010001 sorts the second data sequence into cluster 2, and so on as seen in the table 602 of FIG. 6.

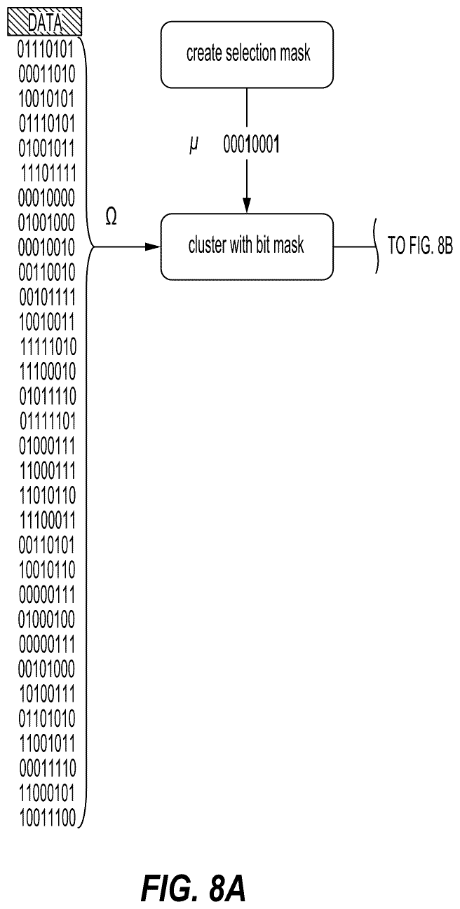

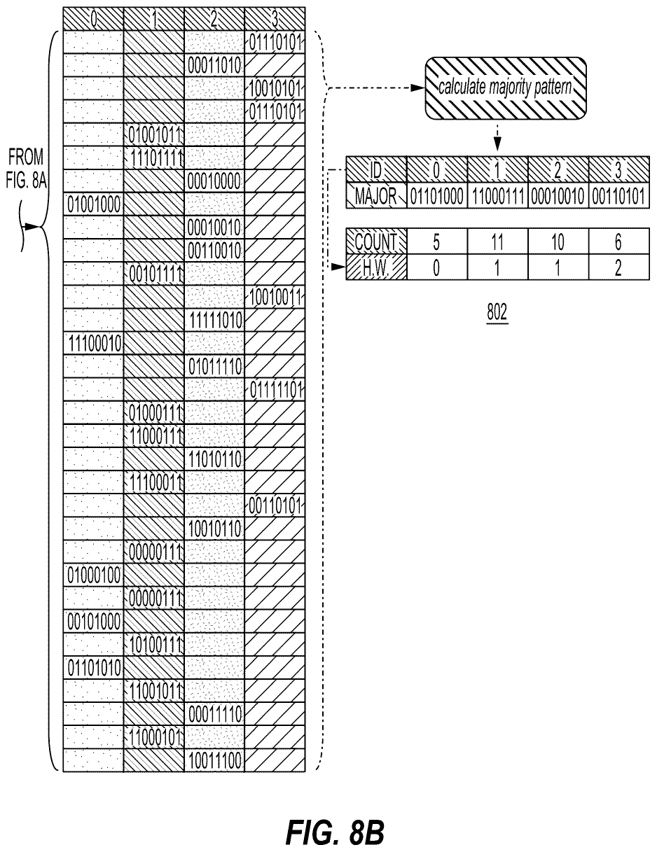

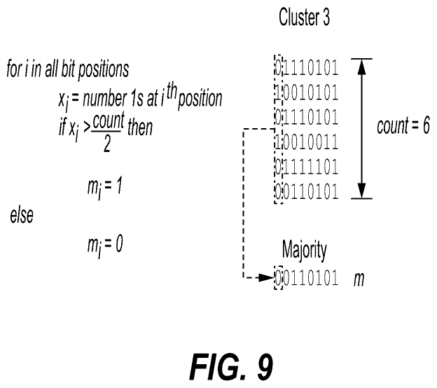

FIGS. 8A, 8B, and 9 are diagrams illustrating calculating of majority bit patterns, in accordance with various aspects of the present disclosure. as shown in FIG. 8A, calculating the majority bit patterns for clusters is based on the number of 1s in the cluster ID, also known as the Hamming weight. The Hamming weight is computed for every cluster ID, as seen in table 802 in FIG. 8B. Thus, the cluster ID 11 has a Hamming weight of 2. The cluster IDs 01 and 10 have Hamming weights of 1, and the cluster ID 00 has a Hamming weight of 0.

Within each cluster, a majority bit pattern is generated by counting the number of 1s at every bit position of values. The total count of sequences for each cluster (Count) is also calculated. The table 802 of FIG. 8B illustrates the count of sequences (Count: 5, 11, 10, and 6, respectively) for each of the clusters.

FIG. 9 illustrates calculating the majority bit pattern for cluster 3. For each bit position, the number of 1s at that position is counted. If the number of 1s is greater than 50% of the count of sequences in the cluster (Count), then the majority bit for that bit position is 1. Otherwise, the majority bit for that position is 0. In the example of FIG. 9, two 1s are present in the leftmost bit position across all of cluster 3's sequences, resulting in a 0 majority bit for the leftmost bit position. The other bit positions are calculated in a similar manner resulting in a majority bit pattern of 00110101 for cluster 3. The other majority bit patterns for the clusters 0, 1, and 2 are calculated the same way, resulting in the majority bit patterns seen in the table 802 of FIG. 8B.

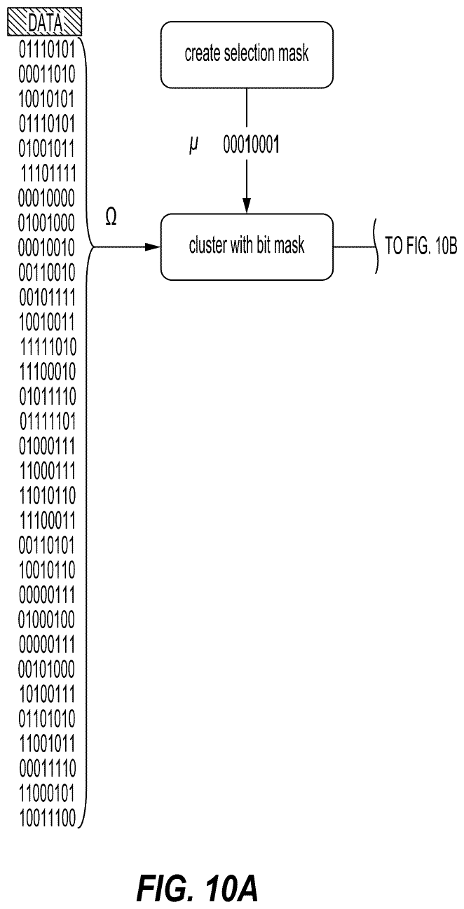

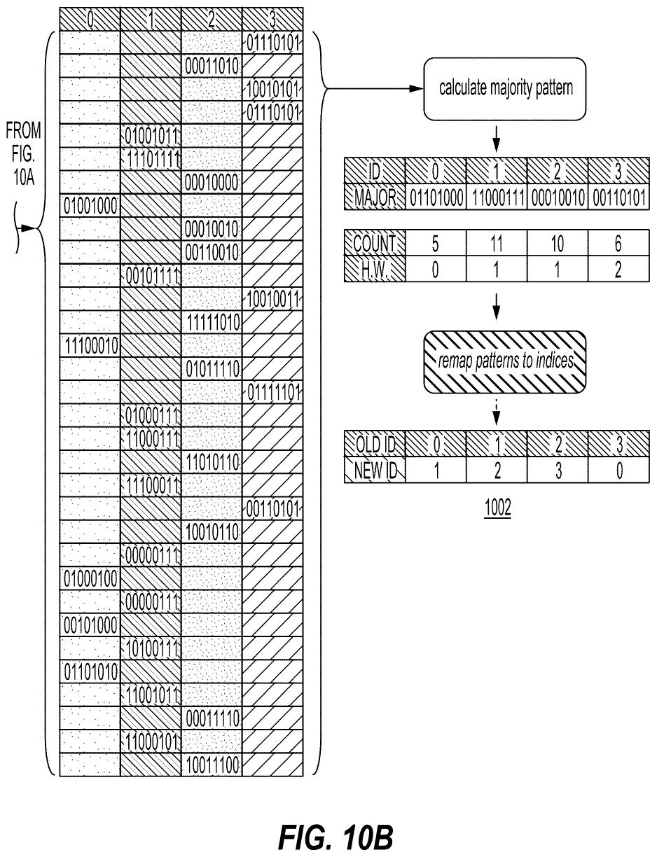

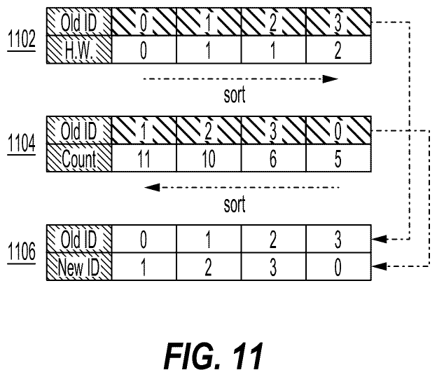

FIGS. 10A, 10B, and 11 are diagrams illustrating remapping of cluster identifiers (IDs), in accordance with various aspects of the present disclosure. Remapping cluster IDs reduces the total number of 1s in the final codes. Thus, low Hamming weight (H.W.) IDs are assigned to more populated clusters. The old IDs are sorted based on count and Hamming weight, as seen in FIG. 11. A first table 1102 showing an ascending sort is based on Hamming weight, and a second table 1104 showing a descending sort is based on a count of sequences in the cluster. Low counts are assigned to high Hamming weights, as seen in a third table 1106 of FIG. 11 and table 1002 of FIG. 10B.

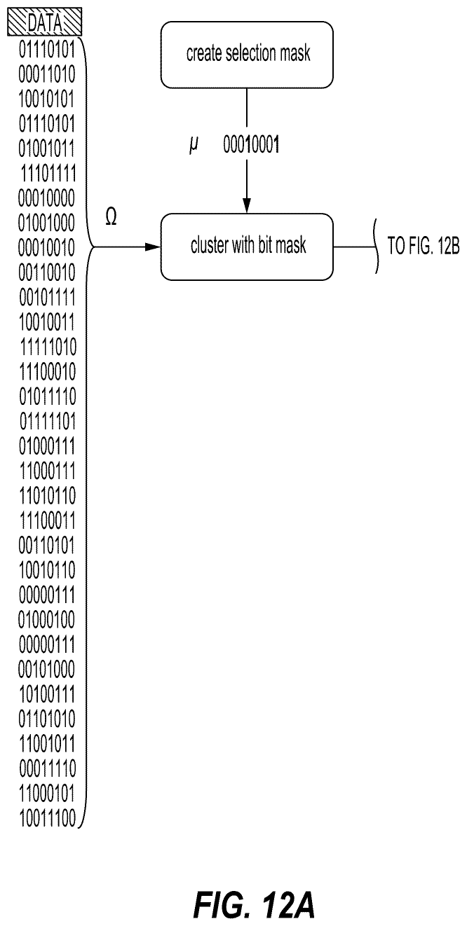

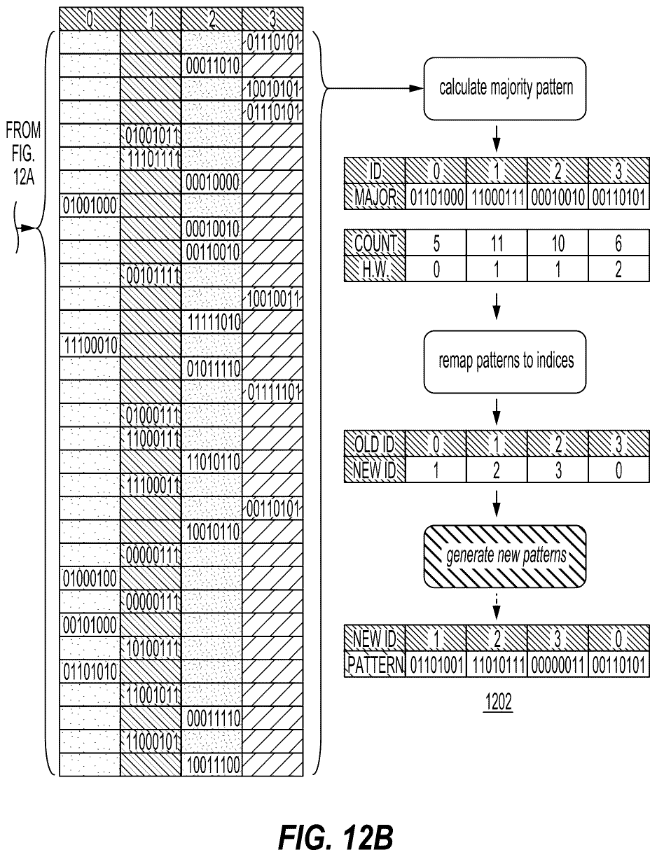

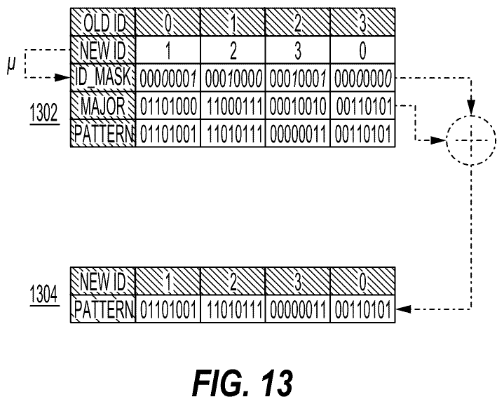

FIGS. 12A, 12B, and 13 are diagrams illustrating coding pattern generation, in accordance with various aspects of the present disclosure. After assigning new IDs to the clusters, the majority bit pattern of each cluster is modified based on its new ID. The new majority bit pattern is calculated based on the ID masks bitwise logically exclusively OR'ed (XOR also represented as ⊕) with the old majority bit patterns.

The ID masks are based on the new IDs. For example, as seen in FIG. 13, a new ID 1 has a binary representation 01. The 0 and 1 are substituted into the bit positions having 1s in the bit selection mask μ. For the new ID 1, the resulting ID mask is 00000001. For a new ID 2 (with binary representation 10), the resulting ID mask is 0001000. For a new ID 3 (with binary representation 11), the resulting ID mask is 0001001. For a new ID 0 (with binary representation 00), the resulting ID mask is 0000000.

The results of bitwise exclusively OR'ing the ID masks for the new IDs (NEW ID) with the majority bit patterns of the old IDs (MAJOR) results in new patterns (PATTERN), as seen in rows 1302, 1304 of FIG. 13 and table 1202 of FIG. 12B.

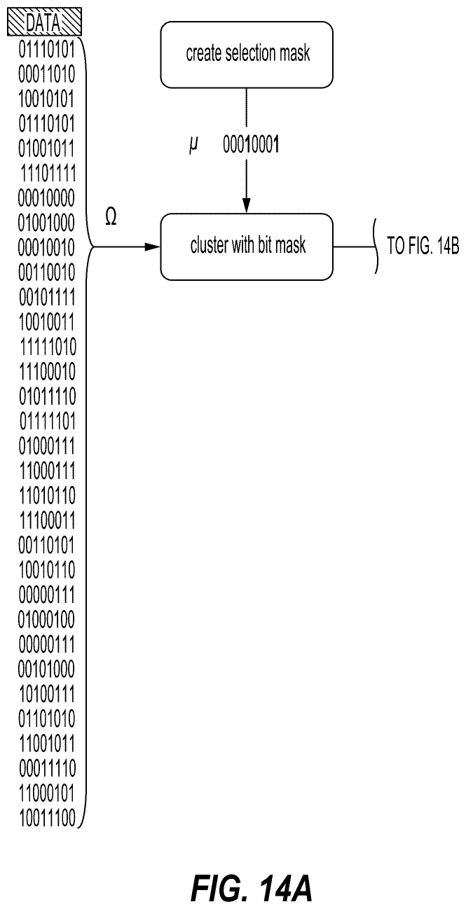

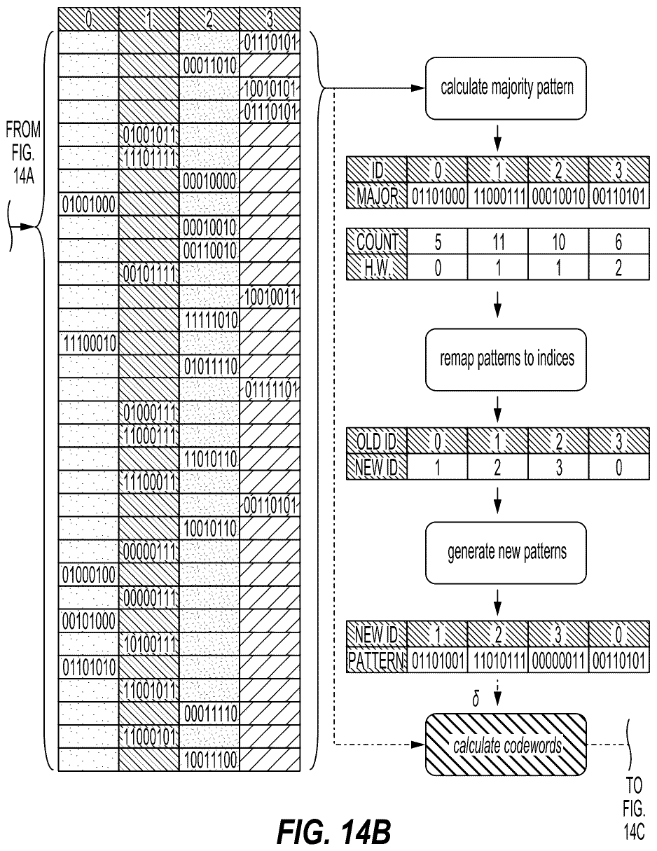

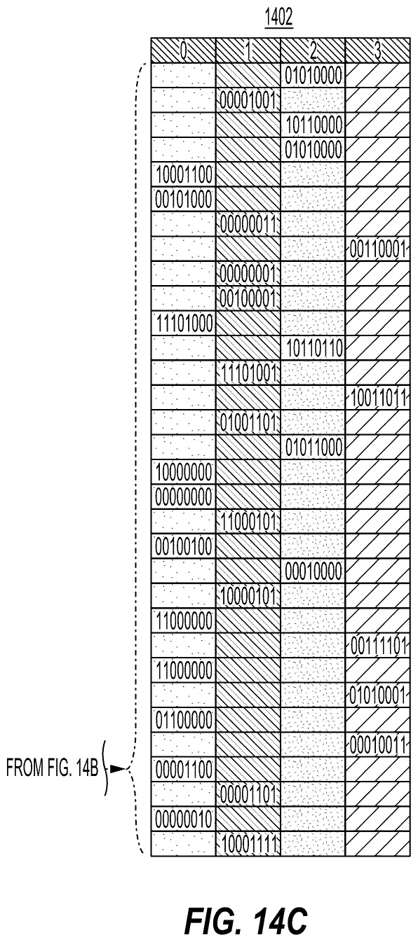

FIGS. 14A-14C are diagrams illustrating codeword calculation, in accordance with various aspects of the present disclosure. The codewords Σ for each cluster are calculated by bitwise logically exclusively OR'ing (XOR) the patterns δ with the original input data sequence Ω, in other words: Σ=δ⊕Ω. For example, looking at the first sequence in old ID 3:01110101, a bitwise XOR operation with the pattern from new ID 0:00110101 results in 01010000. Similar operations are performed for all of the remaining input data sequences Ω. The cluster groups are then rearranged based on the old ID to new ID mapping. For example, the sequences originally in cluster 3 end up in new cluster 2, the sequences originally in cluster 2 end up in new cluster 1, etc., as seen in codeword table 1402 of FIG. 14C.

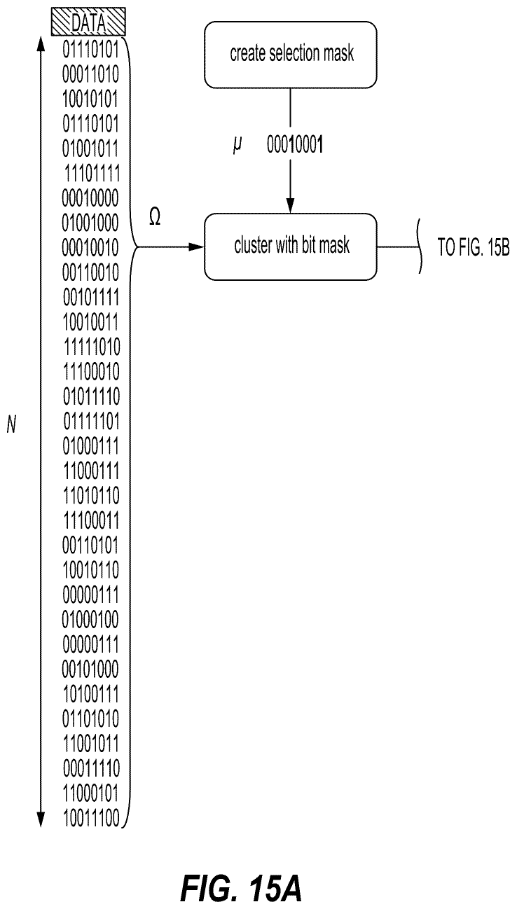

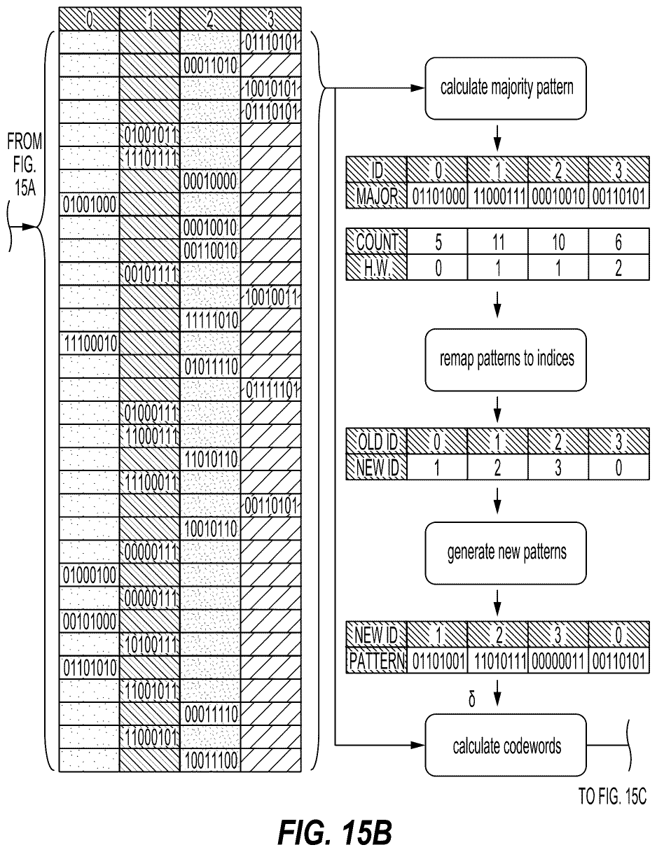

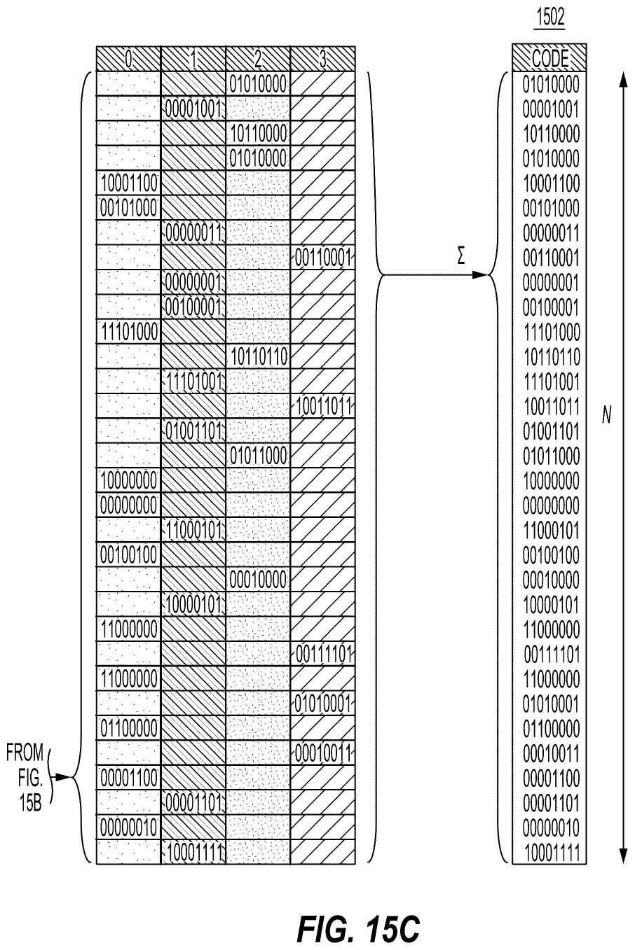

FIGS. 15A-15C are diagrams illustrating data value replacement, in accordance with various aspects of the present disclosure. In the example shown FIG. 15C, a code 1502 is created by replacing input data sequence values Ω with the newly generated codewords. The code 1502 has fewer 1s than the original input data sequences Ω.

The efficiency of the encoding depends on the size of the pattern table, the number N of input data sequences Ω, and the total number b of 1s in the codewords. In the examples of FIGS. 5-15C, the

$$overhead = \frac{{2}^{b} + 1}{N} ≅ 0.12 ,$$

where the overhead represents the additional metadata needed for encoding the number N of input data sequences Ω. Because the value of the number N is small in this example, the overhead of 0.12 is relatively large, compared to a data set with a larger value of the number N. The reduction in the number of 1s is calculated as

$$ratio = \frac{H . W . ( DATA )}{H . W . ( CODE )} ≅ 0.067 ,$$

where the reduction is 0.067 for the data in the examples of FIGS. 5-15C.

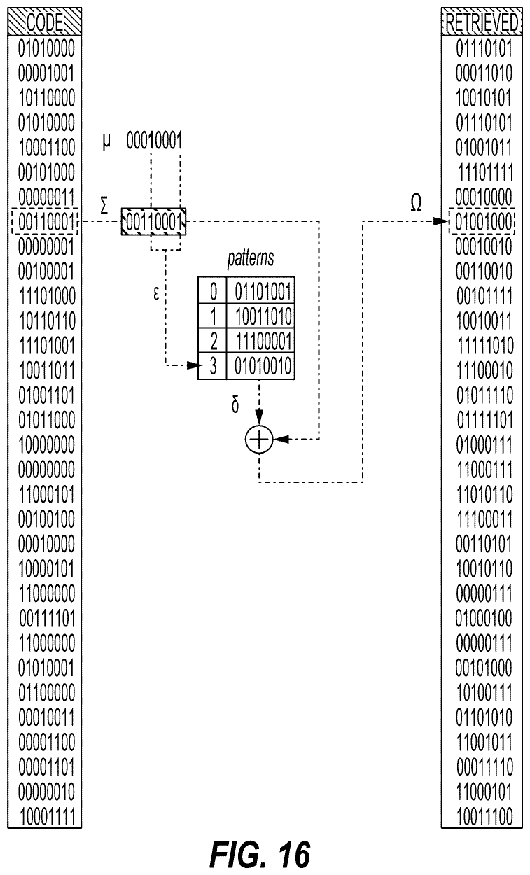

Retrieving the original data from codewords using the pattern table, or decoding, is now described. FIG. 16 is a diagram illustrating data decoding, in accordance with various aspects of the present disclosure. The processing cores need to decode the data before computation. The decoder mechanism may be implemented in software for a CPU, NPU, and/or GPU. For decoding, an index ε is generated for each codeword Σ using the selection mask μ. That is, a bitwise logical AND operation is performed for each input sequence (e.g., codeword) Σ and the selection mask μ. A pattern δ is then read from the table using the index ε. The original input data sequence 22 is retrieved by bitwise logically XOR'ing the pattern δ and the codeword Σ.

In the example of FIG. 16, the codeword Σ 00110001 is logically AND'ed with the selection mask μ: 00010001 to obtain index 3 (binary 11). Based on the index of 3, the pattern δ 01010010 is XOR'ed with the codeword Σ 00110001. The result is 01001000, which corresponds to the original input data sequence Ω.

The proposed encoding mechanism is compatible with ML accelerators from edge devices to data centers, reducing the power consumption of data movement in off-chip interconnects. The proposed solution opens another dimension to ML optimization, supplementing the existing performance optimization techniques. The proposed mechanism relies on computationally simple operations (e.g., table lookup and bitwise XOR) to keep the performance overhead low. The proposed solution comprises encoding (offline or online) and decoding (online) for energy-efficient model inference. The offline encoding mechanism explores the size of the pattern table and all possible pattern values to maximize power saving while keeping the overhead low. The proposed mechanism may be included in any kernel of a CPU, GPU, and/or neural signal processor (NSP). In some examples, if necessary, the proposed mechanism may be included in the hardware of the CPU, GPU, and/or NSP.

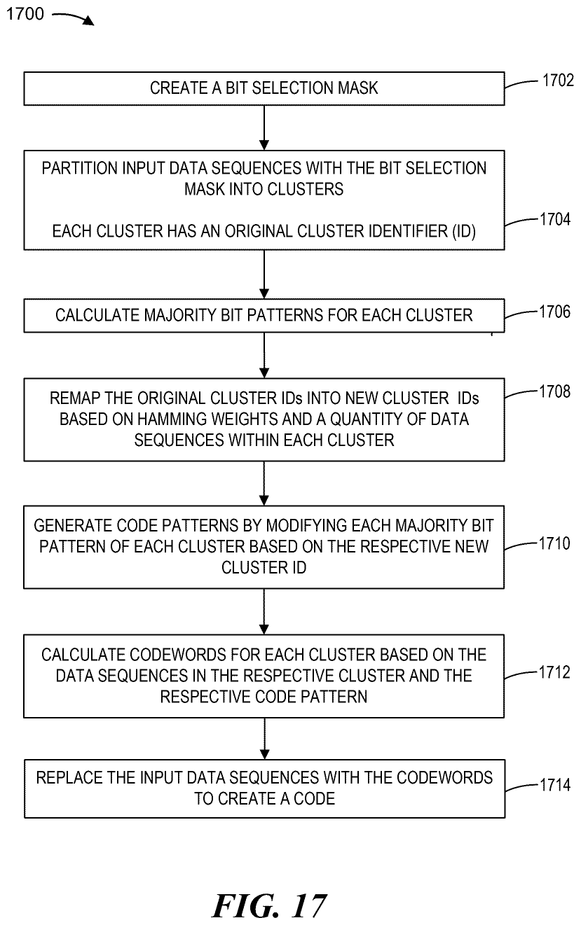

FIG. 17 is a flow diagram illustrating an example process 1700 performed, for example, by a computing device, in accordance with various aspects of the present disclosure. The example process 1700 is an example of encoding data to save power during data transfers.

As shown in FIG. 17, in some aspects, the process 1700 may include creating a bit selection mask (block 1702). In some aspects, the process 1700 may include partitioning input data sequences with the bit selection mask into clusters. Each cluster has an original cluster identifier (ID) (block 1704). In some implementations, the partitioning comprises performing a logical AND operation with the input data sequences and the bit selection mask; and shifting bits from an output of the logical AND operation.

In some aspects, the process 1700 may include calculating majority bit patterns for each cluster (block 1706). In some implementations, calculating the majority bit patterns includes counting a quantity of ones (1s) in each bit position of the cluster and setting the bit position to one if the quantity for the bit position is greater than half of a total count of data sequences for a respective cluster.

In some aspects, the process 1700 may include remapping the original cluster IDs into new cluster IDs based on Hamming weights and a quantity of data sequences within each cluster (block 1708). In some aspects, the process 1700 may include generating code patterns by modifying each majority bit pattern of each cluster based on the respective new cluster ID (block 1710). In some implementations, generating the code patterns includes performing a logical exclusive OR operation with the majority bit pattern of each cluster and the respective new cluster ID.

In some aspects, the process 1700 may include calculating codewords for each cluster based on the data sequences in the respective cluster and the respective code pattern (block 1712). In some implementations, calculating the codewords includes performing a logical exclusive OR operation with the data sequences in the respective cluster and the respective code pattern. The process 1700 may include replacing the input data sequences with the codewords to create a code (block 1714).

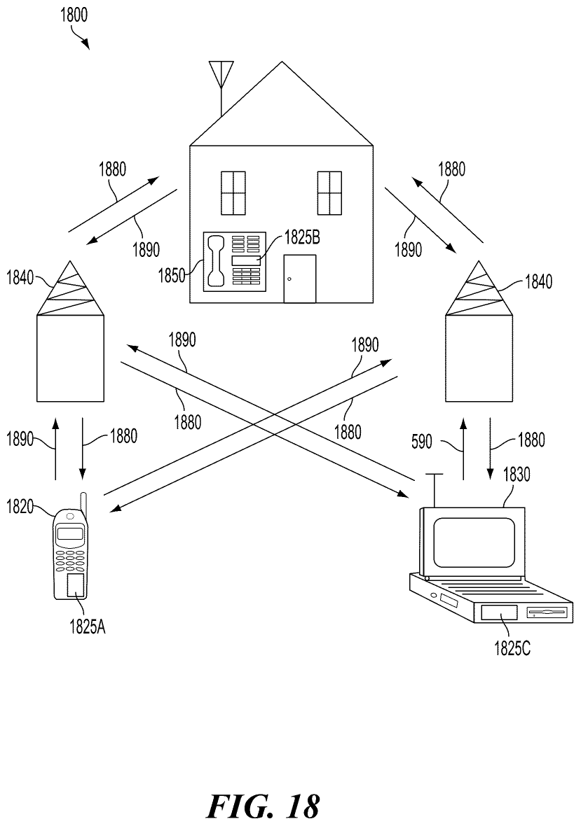

FIG. 18 is a block diagram showing an exemplary wireless communications system 1800, in which an aspect of the present disclosure may be advantageously employed. For purposes of illustration, FIG. 18 shows three remote units 1820, 1830, and 1850, and two base stations 1840. It will be recognized that wireless communications systems may have many more remote units and base stations. Remote units 1820, 1830, and 1850 include integrated circuit (IC) devices 1825A, 1825B, and 1825C that include the disclosed data decoder and encoder. It will be recognized that other devices may also include the disclosed data decoder and encoder, such as the base stations, switching devices, and network equipment. FIG. 18 shows forward link signals 1880 from the base stations 1840 to the remote units 1820, 1830, and 1850, and reverse link signals 1890 from the remote units 1820, 1830, and 1850 to the base stations 1840.

In FIG. 18, remote unit 1820 is shown as a mobile telephone, remote unit 1830 is shown as a portable computer, and remote unit 1850 is shown as a fixed location remote unit in a wireless local loop system. For example, the remote units may be a mobile phone, a hand-held personal communication systems (PCS) unit, a portable data unit, such as a personal data assistant, a GPS enabled device, a navigation device, a set top box, a music player, a video player, an entertainment unit, a fixed location data unit, such as meter reading equipment, or other device that stores or retrieves data or computer instructions, or combinations thereof. Although FIG. 18 illustrates remote units according to the aspects of the present disclosure, the disclosure is not limited to these exemplary illustrated units. Aspects of the present disclosure may be suitably employed in many devices, which include the disclosed data decoder and encoder.

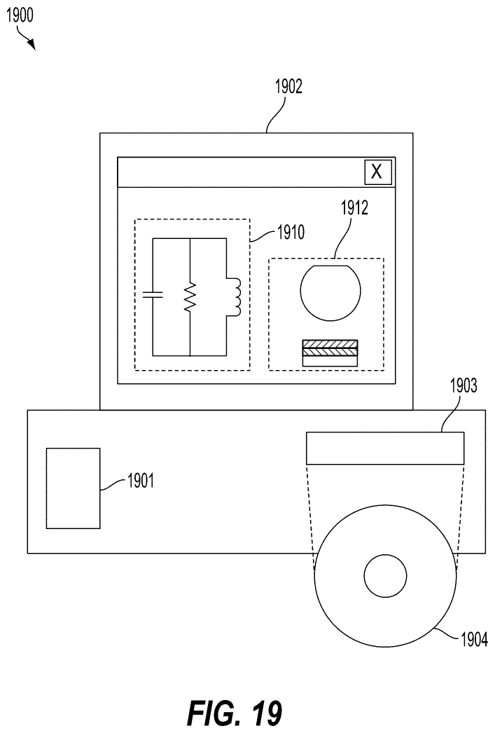

FIG. 19 is a block diagram illustrating a design workstation 1900 used for circuit, layout, and logic design of a semiconductor component, such as the data decoder and encoder disclosed above. The design workstation 1900 includes a hard disk 1901 containing operating system software, support files, and design software such as Cadence or OrCAD. The design workstation 1900 also includes a display 1902 to facilitate design of a circuit 1910 or a semiconductor component 1912, such as the disclosed data decoder and encoder. A storage medium 1904 is provided for tangibly storing the design of the circuit 1910 or the semiconductor component 1912 (e.g., the PLD). The design of the circuit 1910 or the semiconductor component 1912 may be stored on the storage medium 1904 in a file format such as GDSII or GERBER. The storage medium 1904 may be a CD-ROM, DVD, hard disk, flash memory, or other appropriate device. Furthermore, the design workstation 1900 includes a drive apparatus 1903 for accepting input from or writing output to the storage medium 1904.

Data recorded on the storage medium 1904 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1904 facilitates the design of the circuit 1910 or the semiconductor component 1912 by decreasing the number of processes for designing semiconductor wafers.

### EXAMPLE ASPECTS

Aspect 1: A method of data processing, comprising: creating a bit selection mask; partitioning input data sequences with the bit selection mask into clusters, each cluster having an original cluster identifier (ID); calculating majority bit patterns for each cluster; remapping the original cluster IDs into new cluster IDs based on Hamming weights and a quantity of data sequences within each cluster; generating code patterns by modifying each majority bit pattern of each cluster based on the respective new cluster ID; calculating codewords for each cluster based on the data sequences in the respective cluster and the respective code pattern; and replacing the input data sequences with the codewords to create a code.
Aspect 2: The method of Aspect 1, further comprising retrieving the input data sequences from the code by: generating an index for each codeword of the code by using the bit selection mask; retrieving a pattern corresponding to the index for each codeword; and performing a logical exclusive OR operation with the pattern corresponding to the index for each codeword and the respective codeword in order to obtain the input data sequences.
Aspect 3: The method of Aspect 1 or 2, further comprising selecting the bit selection mask by determining a candidate bit selection mask of potential bit selection masks that results in a lowest quantity of ones (1s) in codewords corresponding to the input data sequences.
Aspect 4: The method of Aspect 1, 2, or 3, further comprising selecting the bit selection mask as a random bit selection mask or a predefined bit selection mask.
Aspect 5: The method of any of the preceding Aspects, in which the partitioning comprises: performing a logical AND operation with the input data sequences and the bit selection mask; and shifting bits from an output of the logical AND operation.
Aspect 6: The method of any of the preceding Aspects, in which calculating the majority bit patterns comprises counting a quantity of ones (1s) in each bit position of the cluster and setting the bit position to one if the quantity for the bit position is greater than half of a total count of data sequences for a respective cluster.
Aspect 7: The method of any of the preceding Aspects, in which generating the code patterns comprises performing a logical exclusive OR operation with the majority bit pattern of each cluster and the respective new cluster ID.
Aspect 8: The method of any of the preceding Aspects, in which calculating the codewords comprises performing a logical exclusive OR operation with the data sequences in the respective cluster and the respective code pattern.
Aspect 9: The method of any of the preceding Aspects, in which an original order of the input data sequence is the same as a final order of the code.
Aspect 10: An apparatus for data processing, comprising: at least one memory; and at least one processor coupled to the at least one memory, the at least one processor configured: to create a bit selection mask; to partition input data sequences with the bit selection mask into clusters, each cluster having an original cluster identifier (ID); to calculate majority bit patterns for each cluster; to remap the original cluster IDs into new cluster IDs based on Hamming weights and a quantity of data sequences within each cluster; to generate code patterns by modifying each majority bit pattern of each cluster based on the respective new cluster ID; to calculate codewords for each cluster based on the data sequences in the respective cluster and the respective code pattern; and to replace the input data sequences with the codewords to create a code.
Aspect 11: The apparatus of Aspect 10, in which the at least one processor is further configured: to retrieve the input data sequences from the code; to generate an index for each codeword of the code by using the bit selection mask; to retrieve a pattern corresponding to the index for each codeword; and to perform a logical exclusive OR operation with the pattern corresponding to the index for each codeword and the respective codeword in order to obtain the input data sequences.
Aspect 12: The apparatus of Aspect 10 or 11, in which the at least one processor is further configured to select the bit selection mask by determining a candidate bit selection mask of potential bit selection masks that results in a lowest quantity of ones (1s) in codewords corresponding to the input data sequences.
Aspect 13: The apparatus of Aspect 10, 11, or 12, in which the at least one processor is further configured to select the bit selection mask as a random bit selection mask or a predefined bit selection mask.
Aspect 14: The apparatus of any of the Aspects 10-13, in which the at least one processor is further configured: to perform a logical AND operation with the input data sequences and the bit selection mask; and to shift bits from an output of the logical AND operation.
Aspect 15: The apparatus of any of the Aspects 10-14, in which the at least one processor is further configured to count a quantity of ones (1s) in each bit position of the cluster and set the bit position to one if the quantity for the bit position is greater than half of a total count of data sequences for a respective cluster.
Aspect 16: The apparatus of any of the Aspects 10-15, in which the at least one processor is further configured to perform a logical exclusive OR operation with the majority bit pattern of each cluster and the respective new cluster ID.
Aspect 17: The apparatus of any of the Aspects 10-16, in which the at least one processor is further configured to perform a logical exclusive OR operation with the data sequences in the respective cluster and the respective code pattern.
Aspect 18: The apparatus of any of the Aspects 10-17, in which an original order of the input data sequence is the same as a final order of the code.
Aspect 19: A non-transitory computer-readable medium having program code recorded thereon, the program code executed by a processor and comprising: program code to create a bit selection mask; program code to partition input data sequences with the bit selection mask into clusters, each cluster having an original cluster identifier (ID); program code to calculate majority bit patterns for each cluster; program code to remap the original cluster IDs into new cluster IDs based on Hamming weights and a quantity of data sequences within each cluster; program code to generate code patterns by modifying each majority bit pattern of each cluster based on the respective new cluster ID; program code to calculate codewords for each cluster based on the data sequences in the respective cluster and the respective code pattern; and program code to replace the input data sequences with the codewords to create a code.
Aspect 20: The non-transitory computer-readable medium of Aspect 19, in which the program code comprises: program code to retrieve the input data sequences from the code; program code to generate an index for each codeword of the code by using the bit selection mask; program code to retrieve a pattern corresponding to the index for each codeword; and program code to perform a logical exclusive OR operation with the pattern corresponding to the index for each codeword and the respective codeword in order to obtain the input data sequences.

For a firmware and/or software implementation, the methodologies may be implemented with modules (e.g., procedures, functions, and so on) that perform the functions described. A machine-readable medium tangibly embodying instructions may be used in implementing the methodologies described. For example, software codes may be stored in a memory and executed by a processor unit. Memory may be implemented within the processor unit or external to the processor unit. As used, the term “memory” refers to types of long term, short term, volatile, nonvolatile, or other memory and is not limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include random access memory (RAM), read-only memory (ROM), electrically erasable read-only memory (EEPROM), compact disc read-only memory (CD-ROM) or other optical disk storage, magnetic disk storage or other magnetic storage devices, or other medium that can be used to store desired program code in the form of instructions or data structures and that can be accessed by a computer. Disk and disc, as used, include compact disc (CD), laser disc, optical disc, digital versatile disc (DVD), floppy disk, and Blu-ray® disc, where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communications apparatus. For example, a communications apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions, and alterations can be made without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present disclosure is not intended to be limited to the particular configurations of the process, machine, manufacture, composition of matter, means, methods, and steps described in the specification. As one of ordinary skill in the art will readily appreciate from the present disclosure, processes, machines, manufacture, compositions of matter, means, methods, or steps, presently existing or later to be developed that perform substantially the same function or achieve substantially the same result as the corresponding configurations described may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the present disclosure may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure may be implemented or performed with a general-purpose processor, a digital signal processor (DSP), an application-specific integrated circuit (ASIC), a field-programmable gate array (FPGA) or other programmable logic device, discrete gate or transistor logic, discrete hardware components, or any combination thereof designed to perform the functions described. A general-purpose processor may be a microprocessor, but, in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the present disclosure may be embodied directly in hardware, in a software module executed by a processor, or in a combination of the two. A software module may reside in RAM, flash memory, ROM, erasable programmable read-only memory (EPROM), EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

The previous description of the present disclosure is provided to enable any person skilled in the art to make or use the present disclosure. Various modifications to the disclosure will be readily apparent to those skilled in the art, and the generic principles defined may be applied to other variations without departing from the spirit or scope of the disclosure. Thus, the present disclosure is not intended to be limited to the examples and designs described, but is to be accorded the widest scope consistent with the principles and novel features disclosed.

What is claimed is:

1. A method of data processing, comprising:
creating a bit selection mask;
partitioning input data sequences with the bit selection mask into clusters, each cluster having an original cluster identifier (ID);
calculating majority bit patterns for each cluster;
remapping the original cluster IDs into new cluster IDs based on Hamming weights and a quantity of data sequences within each cluster;
generating code patterns by modifying each majority bit pattern of each cluster based on the respective new cluster ID;
calculating codewords for each cluster based on the data sequences in the respective cluster and the respective code pattern; and
replacing the input data sequences with the codewords to create a code.

2. The method of claim 1, further comprising retrieving the input data sequences from the code by:
generating an index for each codeword of the code by using the bit selection mask;
retrieving a pattern corresponding to the index for each codeword; and
performing a logical exclusive OR operation with the pattern corresponding to the index for each codeword and the respective codeword in order to obtain the input data sequences.

3. The method of claim 1, further comprising selecting the bit selection mask by determining a candidate bit selection mask of potential bit selection masks that results in a lowest quantity of ones (1s) in codewords corresponding to the input data sequences.

4. The method of claim 1, further comprising selecting the bit selection mask as a random bit selection mask or a predefined bit selection mask.

5. The method of claim 1, in which the partitioning comprises:
performing a logical AND operation with the input data sequences and the bit selection mask; and
shifting bits from an output of the logical AND operation.

6. The method of claim 1, in which calculating the majority bit patterns comprises counting a quantity of ones (1s) in each bit position of the cluster and setting the bit position to one if the quantity for the bit position is greater than half of a total count of data sequences for a respective cluster.

7. The method of claim 1, in which generating the code patterns comprises performing a logical exclusive OR operation with the majority bit pattern of each cluster and the respective new cluster ID.

8. The method of claim 1, in which calculating the codewords comprises performing a logical exclusive OR operation with the data sequences in the respective cluster and the respective code pattern.

9. The method of claim 1, in which an original order of the input data sequence is the same as a final order of the code.

10. An apparatus for data processing, comprising:
at least one memory; and
at least one processor coupled to the at least one memory, the at least one processor configured:
to create a bit selection mask;
to partition input data sequences with the bit selection mask into clusters, each cluster having an original cluster identifier (ID);
to calculate majority bit patterns for each cluster;
to remap the original cluster IDs into new cluster IDs based on Hamming weights and a quantity of data sequences within each cluster;
to generate code patterns by modifying each majority bit pattern of each cluster based on the respective new cluster ID;
to calculate codewords for each cluster based on the data sequences in the respective cluster and the respective code pattern; and
to replace the input data sequences with the codewords to create a code.

11. The apparatus of claim 10, in which the at least one processor is further configured:
to retrieve the input data sequences from the code;
to generate an index for each codeword of the code by using the bit selection mask;
to retrieve a pattern corresponding to the index for each codeword; and
to perform a logical exclusive OR operation with the pattern corresponding to the index for each codeword and the respective codeword in order to obtain the input data sequences.

12. The apparatus of claim 10, in which the at least one processor is further configured to select the bit selection mask by determining a candidate bit selection mask of potential bit selection masks that results in a lowest quantity of ones (1s) in codewords corresponding to the input data sequences.

13. The apparatus of claim 10, in which the at least one processor is further configured to select the bit selection mask as a random bit selection mask or a predefined bit selection mask.

14. The apparatus of claim 10, in which the at least one processor is further configured:
to perform a logical AND operation with the input data sequences and the bit selection mask; and
to shift bits from an output of the logical AND operation.

15. The apparatus of claim 10, in which the at least one processor is further configured to count a quantity of ones (1s) in each bit position of the cluster and set the bit position to one if the quantity for the bit position is greater than half of a total count of data sequences for a respective cluster.

16. The apparatus of claim 10, in which the at least one processor is further configured to perform a logical exclusive OR operation with the majority bit pattern of each cluster and the respective new cluster ID.

17. The apparatus of claim 10, in which the at least one processor is further configured to perform a logical exclusive OR operation with the data sequences in the respective cluster and the respective code pattern.

18. The apparatus of claim 10, in which an original order of the input data sequence is the same as a final order of the code.

19. A non-transitory computer-readable medium having program code recorded thereon, the program code executed by a processor and comprising:
program code to create a bit selection mask;
program code to partition input data sequences with the bit selection mask into clusters, each cluster having an original cluster identifier (ID);
program code to calculate majority bit patterns for each cluster;
program code to remap the original cluster IDs into new cluster IDs based on Hamming weights and a quantity of data sequences within each cluster;
program code to generate code patterns by modifying each majority bit pattern of each cluster based on the respective new cluster ID;
program code to calculate codewords for each cluster based on the data sequences in the respective cluster and the respective code pattern; and
program code to replace the input data sequences with the codewords to create a code.

20. The non-transitory computer-readable medium of claim 19, in which the program code further comprises:
program code to retrieve the input data sequences from the code by:
generating an index for each codeword of the code by using the bit selection mask;
retrieving a pattern corresponding to the index for each codeword; and
performing a logical exclusive OR operation with the pattern corresponding to the index for each codeword and the respective codeword in order to obtain the input data sequences.
